(19) United States
(12) Patent Application Publication
(10) Pub. No.: US 2017/0257970 A1
(43) Pub. Date: Sep. 7, 2017

(54) RACK HAVING UNIFORM BAYS AND AN OPTICAL INTERCONNECT SYSTEM FOR SHELF-LEVEL, MODULAR DEPLOYMENT OF SLEDS ENCLOSING INFORMATION TECHNOLOGY EQUIPMENT

(71) Applicant: Radisys Corporation, Hillsboro, OR (US)

(72) Inventors: Andrew Peter Alleman, Portland, OR (US); Nilanthren V. Naidoo, Beaverton, OR (US); Matthew Power St. Peter, Summerland Key, FL (US)

(21) Appl. No.: 15/442,502

(22) Filed: Feb. 24, 2017

Related U.S. Application Data
(60) Provisional application No. 62/304,090, filed on Mar. 4, 2016.

(51) Int. Cl. H05K 7/14; G06F 1/18; H04Q 1/02

(52) U.S. Cl. CPC H05K 7/1489; H04Q 1/15; H05K 7/1492; G06F 1/187; H04Q 2201/804

(57) ABSTRACT

A rack-based system for carrying information technology equipment has a rack for mounting the equipment. The rack includes multiple uniform bays each sized to receive a server sled. The system includes an optical network having optical interconnect attachment points at a rear of each bay and fiber-optic cabling extending from the optical interconnect attachment points to preselected switching elements. Multiple server sleds including compute sleds and storage sleds are slidable into corresponding bays so as to connect to the optical network using blind mate connectors at a rear of each server sled.

### RELATED APPLICATION

This application claims the benefit of U.S. Provisional Patent Application No. 62/304,090, filed Mar. 4, 2016, which is hereby incorporated by reference herein in its entirety.

### TECHNICAL FIELD

This disclosure generally relates to standardized frames or enclosures for mounting multiple information technology (IT) equipment modules such as a rack mount system (RMS) and, more particularly, to a rack having an optical interconnect system.

### BACKGROUND INFORMATION

Rack mount network appliances, such as computing servers, are often used for high density processing, communication, or storage needs. For example, a telecommunications center may include racks in which network appliances provide to customers communication and processing capabilities as services. The network appliances generally have standardized heights, widths, and depths to allow for uniform rack sizes and easy mounting, removal, or serviceability of the mounted network appliances.

In some situations, standards defining locations and spacing of mounting holes of the rack and network appliances may be specified. Often, due to the specified hole spacing, network appliances are sized accordingly to multiples of a specific minimum height. For example, a network appliance with a minimum height may be referred to as one rack unit (1U) high, whereas the heights of network appliances having about twice or three times that minimum height are referred to as, respectively, 2U or 3U. Thus, a 2U network appliance is about twice as tall as a 1U case, and a 3U network appliance is about three times as tall as the 1U case.

### SUMMARY OF THE DISCLOSURE

A rack-based system including a rack carries information technology equipment housed in server sleds (or simply, sleds). A rack of the system includes multiple uniform bays, each of which is sized to receive a server sled. The system includes an optical network having optical interconnect attachment points at a rear of each bay and fiber-optic cabling extending from the optical interconnect attachment points to preselected switching elements. Multiple server sleds—including compute sleds and storage sleds—are slidable into and out from corresponding bays so as to connect to the optical network using blind mate connectors at a rear of each server sled.

Additional aspects and advantages will be apparent from the following detailed description of embodiments, which proceeds with reference to the accompanying drawings.

### BRIEF DESCRIPTION OF THE DRAWINGS

FIG. 1 is an annotated photographic view of an upper portion of a cabinet encompassing a rack that is subdivided into multiple uniform bays for mounting therein networking, data storage, computing, and power supply unit (PSU) equipment.

FIG. 2 is an annotated photographic view of a modular data storage server unit (referred to as a storage sled) housing a clip of disk drives and sized to be slid on a corresponding full-width shelf into a 2U bay that encompasses the storage sled when it is mounted in the rack of FIG. 1.

FIG. 3 is an annotated photographic view of a modular computing server unit (referred to as a compute sled) housing dual computing servers and sized to be slid on a corresponding left- or right-side half-width shelf into a 2U bay that encompasses the compute sled when it is mounted in the rack of FIG. 1.

FIG. 4 is a front elevation view of a rack according to another embodiment.

FIG. 5 is an annotated block diagram of a front elevation view of another rack, showing an example configuration of shelves and bays for carrying top-of-rack (ToR) switches, centrally stowed sleds, and PSUs mounted within the lower portion of the rack.

FIG. 6 is an enlarged and annotated fragmentary view of the block diagram of FIG. 5 showing, as viewed from the front of the rack and with sleds removed, optical interconnect attachment points mounted on connector panels within each bay at the rear of the rack to allow the sleds of FIGS. 2 and 3 to engage optical connectors when the sleds are slid into corresponding bays, and thereby facilitate optical connections between the sleds and corresponding switching elements of the ToR switches shown in FIG. 5.

FIG. 7 is a photographic view of two of the connector panels represented in FIG. 6, as viewed at the rear of the rack of FIG. 1.

FIG. 8 is a pair of photographic views including upper and lower fragmentary views of a back side of the rack showing (with sleds removed from bays) fiber-optic cabling of, respectively, ToR switch and sled bays in which the cabling extends from the multiple optical interconnect attachment points of FIGS. 6 and 7 to corresponding switching elements of the ToR switches.

FIG. 9 is block diagram showing an example data plane fiber-optic network connection diagram for fiber-optic cabling communicatively coupling first and second (e.g., color-coded) sections of optical interconnect attachment points of bay numbers 1.1-15.1 and switching elements of a ToR data plane switch.

FIG. 10 is block diagram showing an example control plane fiber-optic network connection diagram for fiber-optic cabling between third and fourth (e.g., color-coded) sections of optical interconnect attachment points of bay numbers 1.1-15.1 and switching elements of ToR control plane switches.

FIG. 11 is a block diagram showing in greater detail sleds connecting to predetermined switching elements when the sleds are slid into bays so as to engage the optical interconnect attachment points.

FIG. 12 is an enlarged photographic view showing the rear of a sled that has been slid into a bay so that its optical connector engages an optical interconnect attachment point at the rear of the rack.

FIG. 13 is a photographic view of an optical blind mate connector system (or generally, connector), in which one side (e.g., a male side) of the connector is used at a rear of the sled, and a corresponding side (e.g., a female side) is mounted in the connector panel to facilitate a plug-in connection when the sled slides into a bay and its side of the connector mates with that of the connector panel.

FIG. 14 is a photographic view of the rear of the rack shown with sleds present in the bays.

FIG. 15 is a pair of annotated block diagrams showing front and side elevation views of a compute sled.

### DETAILED DESCRIPTION OF EMBODIMENTS

Some previous rack mount network appliances include chassis that are configured to house a variety of different components. For example, a rack mount server may be configured to house a motherboard, power supply, or other components. Additionally, the server may be configured to allow installation of expansion components such as processor, storage, or input-output (I/O) modules, any of which can expand or increase the server's capabilities. A network appliance chassis may be configured to house a variety of different printed circuit board (PCB) cards having varying lengths. In some embodiments, coprocessor modules may have lengths of up to 13 inches while I/O or storage modules may have lengths of up to six inches.

Other attempts at rack-based systems—e.g., designed under 19- or 23-inch rack standards or under Open Rack by Facebook's Open Compute Project (OCP)—have included subracks of IT gear mounted in the rack frame (or other enclosure) using a hodge-podge of shelves, rails, or slides that vary among different subrack designs. The subracks are then specifically hardwired (e.g., behind the rack wiring) to power sources and signal connections. Such subracks have been referred to as a rack mount, a rack-mount instrument, a rack mount system (RMS), a rack mount chassis, a rack mountable, or a shelf. An example attempt at a subrack for a standard 19-inch rack is described in the open standard for telecom equipment, Advanced Telecommunications Computing Architecture (AdvancedTCA®). In that rack system, each subrack receives cards or modules that are standard for that subrack, but with no commonality among manufacturers. Each subrack, therefore, is essentially its own system that provides its own cooling, power distribution, and backplane (i.e., network connectivity) for the cards or modules placed in the subrack.

In the present disclosure, however, a rack integrated in a cabinet has shelves that may be subdivided into slots to define a collection of uniform bays in which each bay accepts enclosed compute or storage units (i.e., sleds, also referred to as modules) so as to provide common cooling, power distribution, and signal connectivity throughout the rack. The integrated rack system itself acts as the chassis because it provides a common infrastructure including power distribution, cooling, and signal connectivity for all of the modules slid into the rack. Each module may include, for example, telecommunication, computing, media processing, or other IT equipment deployed in data center racks. Accordingly, the integrated rack directly accepts standardized modules that avoid the ad hoc characteristics of previous subracks. It also allows for live insertion or removal of the modules.

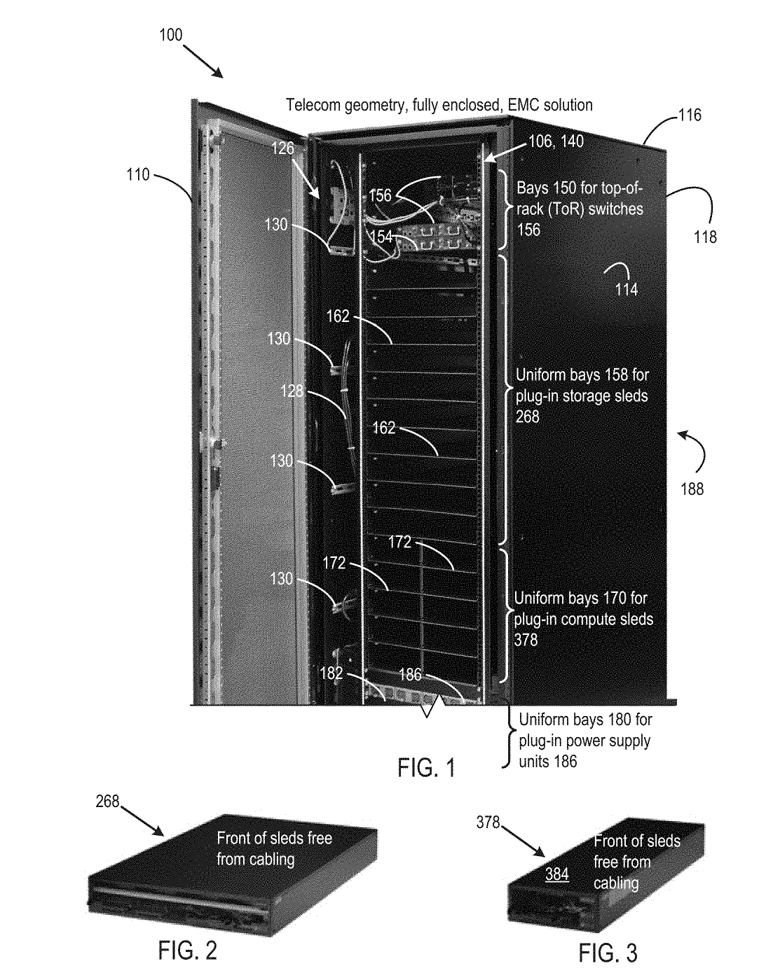

FIG. 1 shows a cabinet 100 enclosing an integrated IT gear mounting rack 106 that is a telecom-standards-based rack providing physical structure and common networking and power connections to a set of normalized subcomponents comprising bays (of one or more rack slots), full- and half-rack-width shelves forming the bays, and sleds. The latter of these subcomponents, i.e., the sleds, are substantially autonomous modules housing IT resources in a manner that may be fairly characterized as further subdividing the rack according to desired chunks of granularity of resources. Thus, the described rack-level architecture includes a hierarchical, nested, and flexible subdivision of IT resources subdivided into four (or more), two, or single chunks that are collectively presented in the rack as a single compute and storage solution, thereby facilitating common and centralized management via an I/O interface. Because each sled is physically connected to one or more switch ports, the rack itself provides for a physical aggregation of multiple modules, and I/O aggregation takes place at the switch level.

Structurally, the cabinet 100 includes a door 110 that swings to enclose the rack 106 within sidewalls 114 and a roof 116 of the cabinet 100. The door 110, sidewalls 114, roof 116, and a back side 118 having crossbar members and beams 820 (FIG. 8) fully support and encompass the rack 106, which is thereby protected for purpose of safety and security (via door locks). The door 110, sidewalls 114, and roof 116 also provide for some reduction in electromagnetic emissions for purpose of compliance with national or international standards of electromagnetic compatibility (EMC).

The interior of the cabinet 100 has three zones. A first zone 126 on sides of the rack 106 extends vertically along the inside of the sidewalls 114 and provides for storage of optical and power cabling 128 within free space of the first zone 126. Also, FIG. 1 shows that there are multiple internal support brackets 130 for supporting the rack 106 and other IT gear mounted in the cabinet 100. A second zone 140 includes the rack 106, which is itself subdivided into multiple uniform bays for mounting (from top to bottom) networking, data storage, computing, and PSU equipment. Specifically, upper 1U bays 150 include (optional) full-width shelves 154 for carrying network switches 156, upper 2U bays 158 include a series of full-width shelves 162 for carrying data storage sleds 268 (FIG. 2), lower 2U bays 170 include a series of side-by-side half-width shelves 172 defining side-by-side slots for carrying compute sleds 378 (FIG. 3), and lower bays 180 include (optional) full-width shelves 182 for carrying PSUs 186. Finally, a third zone 188 along the back side 118 includes free space for routing fiber-optic cabling between groups of optical interconnect attachment points (described in subsequent paragraphs) and switching elements, e.g., Quad Small Form-factor Pluggable (QSFP+) ports, of the network switches 156.

FIGS. 2 and 3 show examples of the sleds 268 and 378. With reference to FIG. 2, the sled 268 includes a clip of (e.g., 24) disk drives that may be inserted or replaced as a single unit by sliding the sled 268 into a corresponding bay 158. With reference to FIG. 3, the compute sled 378 defines a physical container to hold servers, as follows.

The compute sled 378 may contain a group of servers—such as, for example, a pair of dual Intel® Xeon® central processing unit (CPU) servers, stacked vertically on top of each other inside a housing 384—that are deployed together within the rack 106 as a single module and field-replaceable unit (FRU). Although the present disclosure assumes a compute sled contains two servers enclosed as a single FRU, the server group within a sled can be a different number than two, and there could be a different number of compute sleds per shelf (e.g., one, three, or four). For example, a sled could be one server or 4-16 microservers.

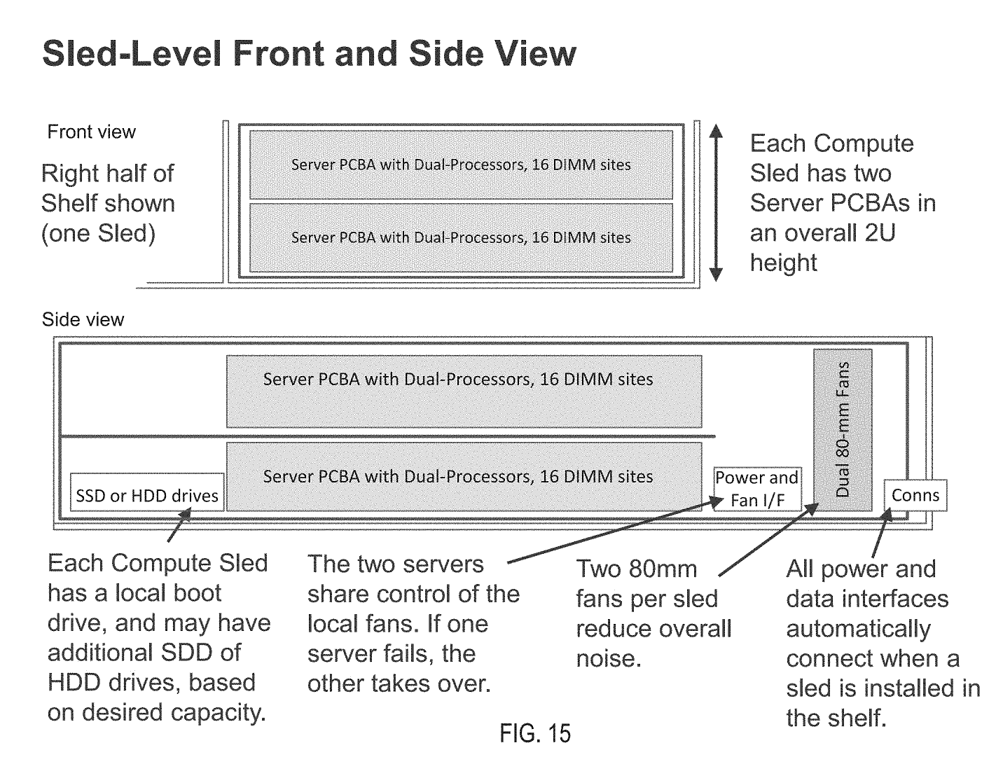

The sleds 268 and 378 offer benefits of modularity, additional shrouding for enhanced EMC, and cooling—but without adding the overhead and complexity of a chassis. For example, in terms of modularity, each sled contains one or more servers, noted previously, that communicate through a common optical interconnect at a back side of the sled for rack-level I/O and management. Rack-level I/O and management are then facilitated by optical cabling (described in detail below) extending within the cabinet 100 between a blind mate socket and the switches, such that preconfigured connections are established between a sled's optical interconnect and the switches when a sled is slid into the rack 106. Relatedly, and in terms of shrouding, front faces of sleds are free from cabling because each sled's connections are on its back side: a sled receives from a PSU power delivered through a plug-in DC rail (in the rear of each sled). Cooling is implemented per-sled and shared across multiple servers within the sled so that larger fans can be used (see, e.g., FIG. 15). Cool air is pulled straight through the sled so there is no superfluous bending or redirection of airflow. Accordingly, the rack 106 and the sleds 268 and 378 provide a hybrid of OCP and RMS approaches.

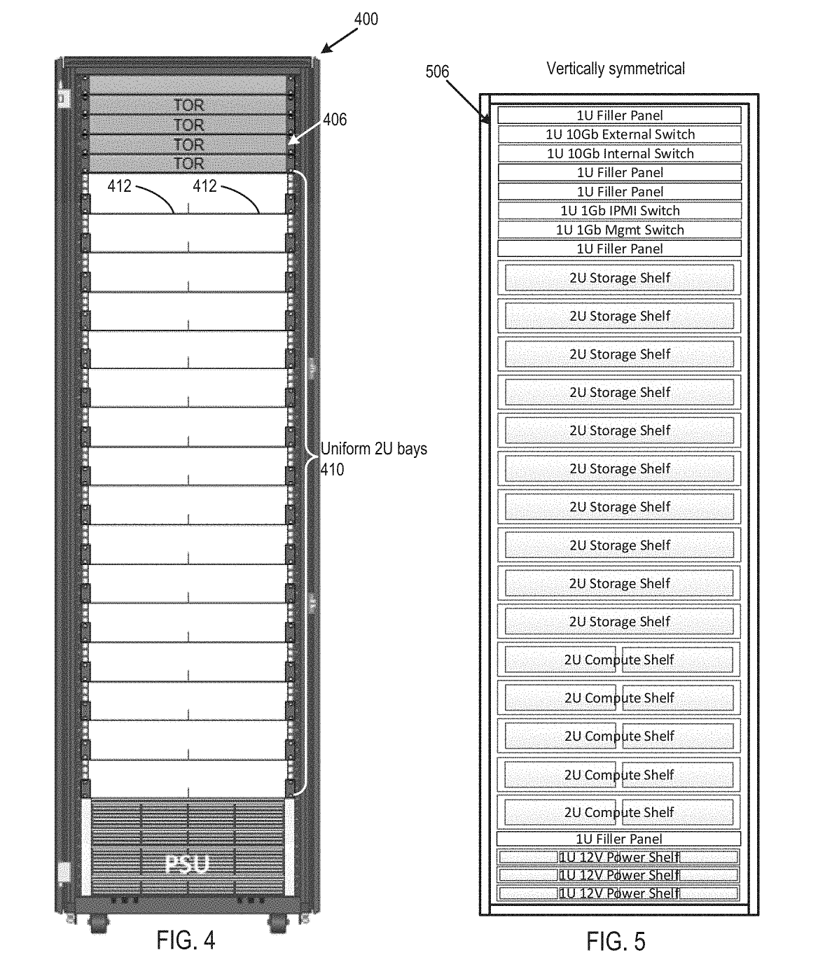

FIG. 4 shows another embodiment of a cabinet 400. The cabinet 400 includes a rack 406 that is similar to the rack 106 of FIG. 1, but each 2U bay 410 has a half-width shelf that defines two slots 412 for carrying up to two sleds side-by-side. FIG. 5 shows another example configuration of a rack 506. Each of the racks 106, 406, and 506, however, has an ability to support different height shelves and sleds for heterogeneous functions. The examples are intended to show that the shelf and sled architecture balances flexibility and granularity to support a variety of processing and storage architectures (types and footprints) aggregated into a simple mechanical shelf system for optimal installation and replacement of sleds.

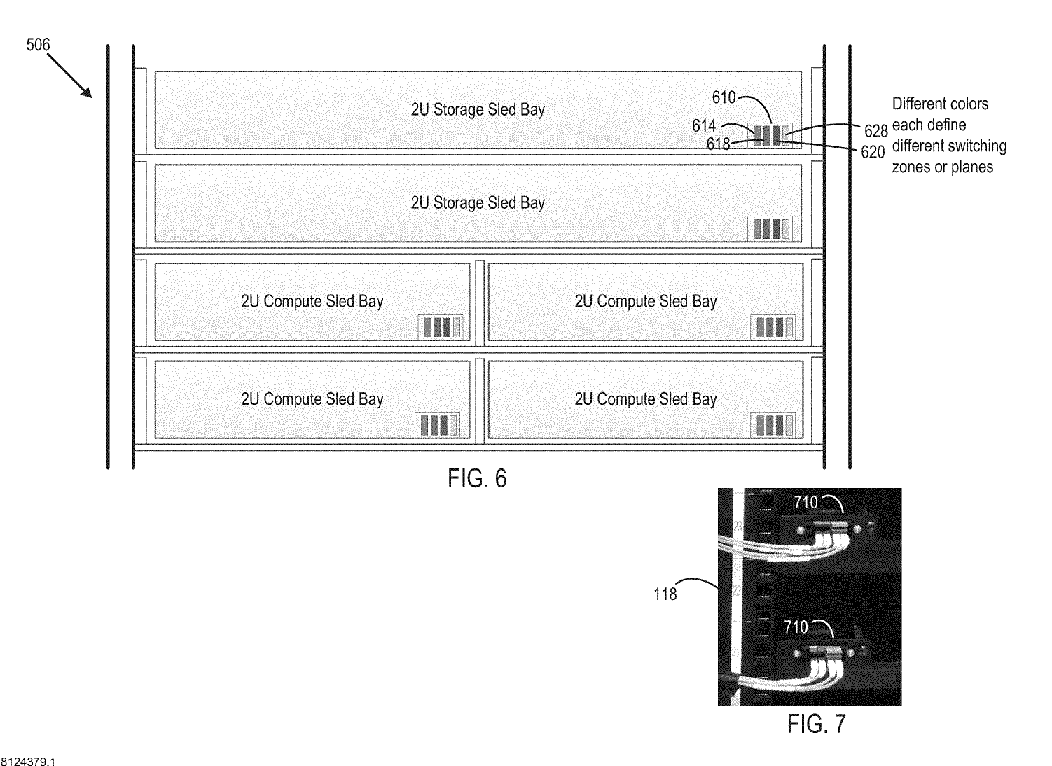

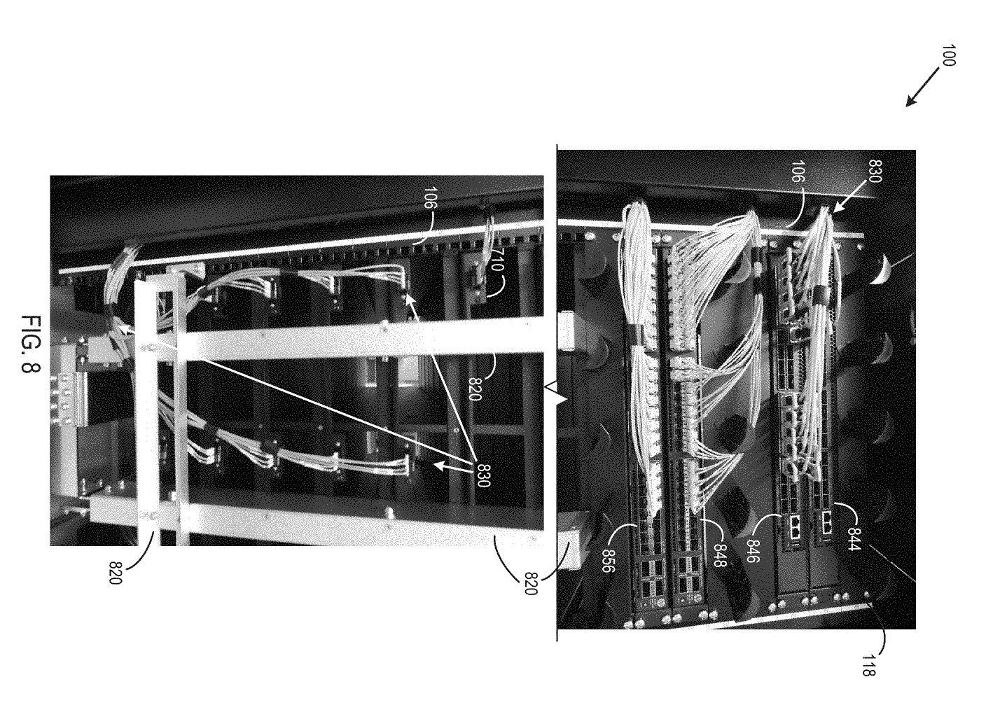

FIGS. 6-11 show examples of an optical network established upon sliding sleds into racks. FIG. 6, for example, is a detail view of a portion of the rack 506. When viewing the rack 506 from its front and without sleds present in bays, groups of optical connectors 610 can be seen at the back right-side lower corner of each bay in the rack 506. Each group 610 has first 614, second 618, third 620, and fourth 628 optical connector sections, which are color-coded in some embodiments. Similarly, FIG. 7 shows how groups of optical connectors 710 are affixed at the back side 118 of the rack 106 to provide attachment points for mating of corresponding connectors of sleds and bays so as to establish an optical network 830 shown in FIG. 8. An upper view of FIG. 8 shows fiber-optic cabling extending from switches 844, 846, 848, and 856. A lower view shows fiber-optic cabling extending to the groups of optical connectors 710 that connect switches to bays.

In this example, each rack can be equipped with a variable number of management plane and data plane switches (ToR switches). Each of these aggregate management and data traffic to internal network switch functions, as follows.

With reference to the primary data plane switch 844, all servers in the rack connect to the downlinks of the primary data plane switch using their first 10 GbE (Gigabit Ethernet) port. The switch uplink ports (40 GbE) provide external connectivity to a cluster or end-of-row (EoR) aggregation switches in a datacenter.

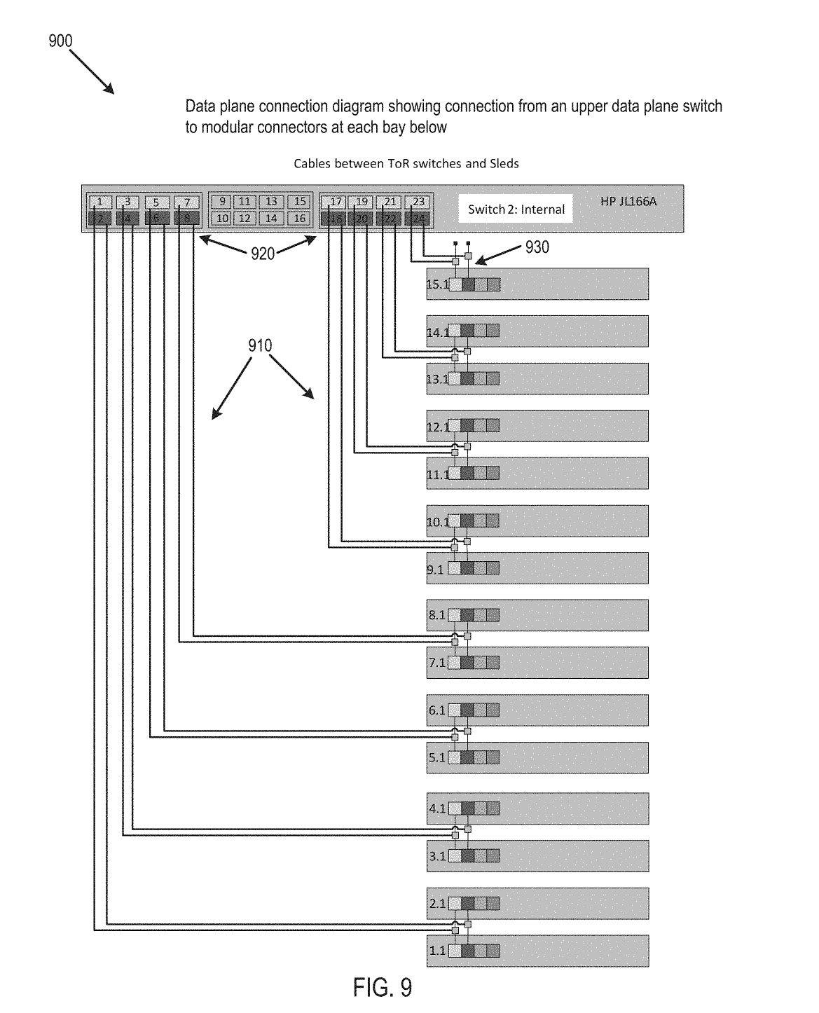

With reference to the secondary data plane switch 846 (see, e.g., “Switch 2” of FIG. 9), all servers in the rack connect to the downlinks of the secondary dataplane switch using their second 10 GbE port. This switch uplink ports (40 GbE) provide external connectivity to the cluster or EoR aggregation switches in the datacenter.

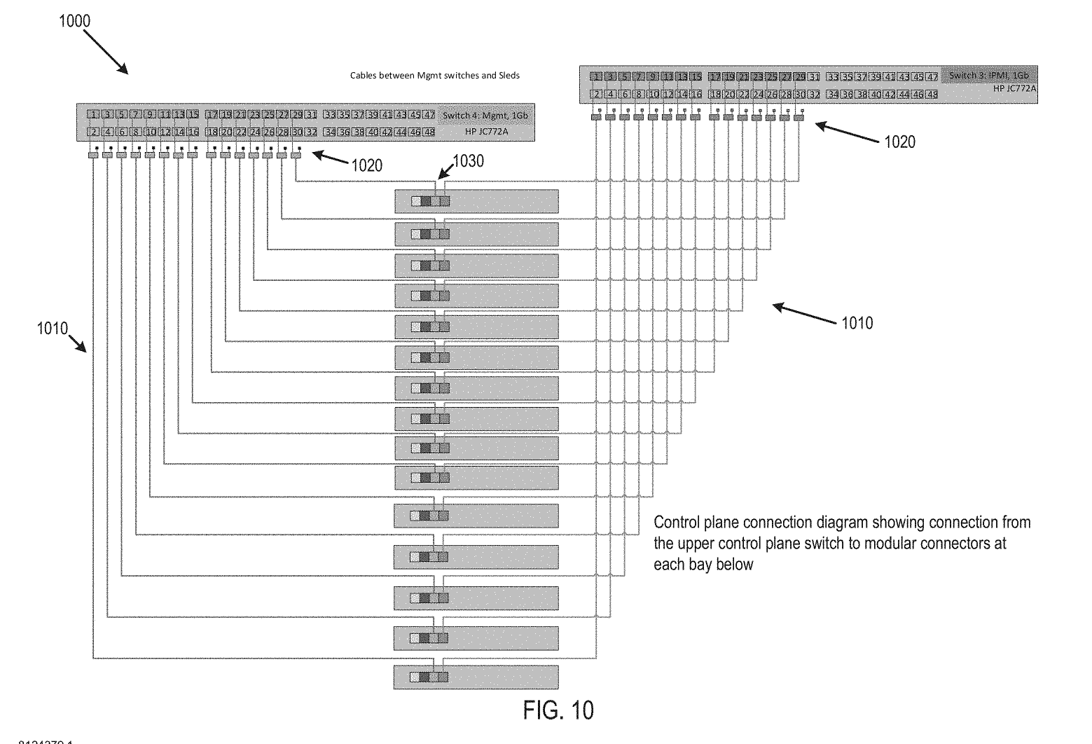

With reference to the device management switch 848 (see, e.g., “Switch 3” of FIG. 10), the 1 GbE Intelligent Platform Management Interface (IPMI) management ports (i.e. blind mate connector port) of each of the rack component (i.e. servers, switches, power control, etc.) are connected to the downlink ports on the switch. The uplink ports (10 GbE) can be connected to the cluster EoR aggregation switches in the datacenter.

With reference to the application management switch 856 (see, e.g., “Switch 4” of FIG. 10), all servers in the rack connect to this switch using a lower speed 1 GbE port. This switch provides connectivity between the rack servers and external cluster or EoR switches to an application management network. The uplink ports (10 GbE) connect to the application management spine switches.

Although the switch topology is not a fixed system requirement, a rack system will typically include at least a device management switch and primary data plane switch. Redundancy may or may not be part of the system configuration, depending on the application usage.

FIG. 8 also indicates that each network uses a different one of the color-coded optical connector sections (i.e., a different color-coded section) that are each located in the same position at each bay so that (upper) switch connections act as a patch panel to define sled functions by bay. A technician can readily reconfigure the optical fiber connections at the switches to change the topology of the optical network 830 without changing anything at the bay or sled level. Thus, the upper connections can be moved from switch to switch (network to network) to easily reconfigure the system without any further changes made or planned at the sled level. Example topologies are explained in further detail in connection with FIGS. 9-11. Initially, however, a brief description of previously attempted backplanes and patch panels is set forth in the following two paragraphs.

Advanced TCA and other bladed telecom systems have a backplane that provides the primary interconnect for the IT gear components. Backplanes have an advantage of being hot swappable, so that modules can be replaced without disrupting any of the interconnections. A disadvantage is that the backplane predefines a maximum available bandwidth based on the number and speed of the channels available.

Enterprise systems have also used patch panel wiring to connect individual modules. This has an advantage over backplanes of allowing channels to be utilized as needed. It has a disadvantage in that, during a service event, the cables have to be removed and replaced. And changing cables increases the likelihood of operator-induced system problems attributable to misallocated connections of cables, i.e., connection errors. Also, additional time and effort would be expended removing and replacing the multiple connections to the equipment and developing reference documentation materials to track the connections for service personnel.

In contrast, FIGS. 9 and 10 show how optical networks (i.e., interconnects and cabling) of the racks 106, 406, and 506 leverage advantages of conventional backplanes and patch panels. The integrated rack eliminates a so-called backplane common to most subrack-based systems. Instead, it provides a patch panel mechanism to allow for each rack installation to be customized for a particular application, and adapted and changed for future deployments. The optical network allows any interconnect mechanism to be employed while supporting live insertion of the front module. For example, FIG. 9 shows a data plane diagram 900 and FIG. 10 shows a control plane diagram 1000 in which cabling 910 and 1010 of an optical network has been preconfigured according to the customer's specific network topology so that the optical network acts like a normal fixed structured backplane. But the optical network can also be reconfigured and changed to accommodate different rack-level (or group of rack-level) stock keeping units (SKUs) simply by changing the cable arrangement between switch connections 920 and 1020 and optical interconnect attachment points 930 and 1030. The flexibility of the optical network also allows for readily upgrading hardware to accommodate higher performance configurations, such as, for example, 25, 50, or 100 gigabit per second (Gbps) interconnects.

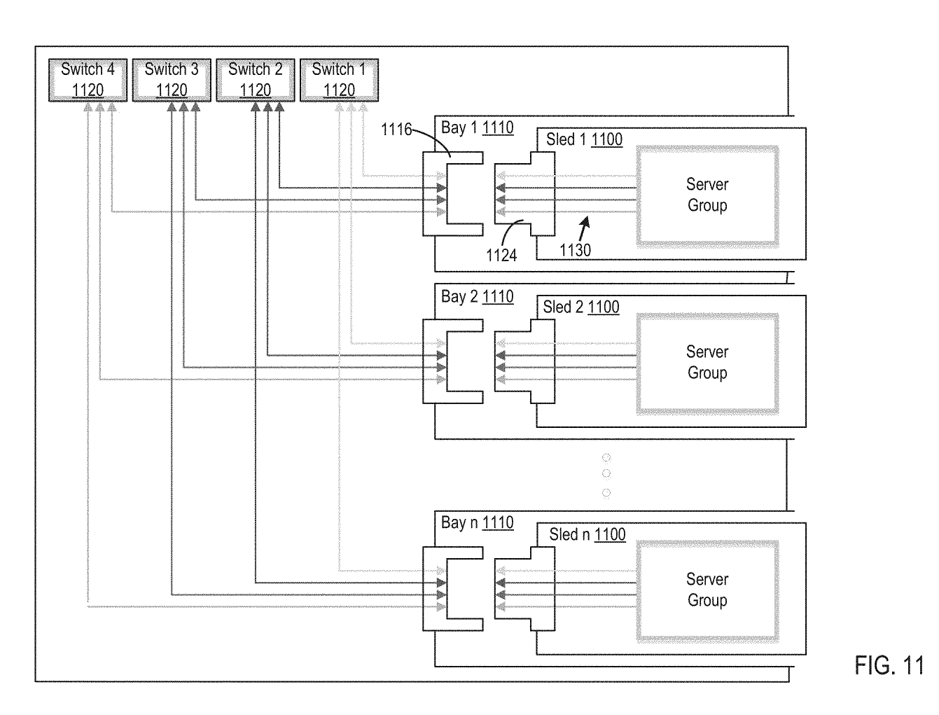

FIG. 11 shows an example of how sleds 1100 connect automatically when installed in bays 1110. In this example, each bay 1110 has a female connector 1116 that presents all of the rack-level fiber-optic cable connections from four switches 1120. Each female connector 1116 mates with a male counterpart 1124 at the back of each sled 1100. The sled 1100 has its optical connector component of the male counterpart 1124 in the rear, from which a bundle of optical networking interfaces (e.g., serialized Ethernet) 1130 are connected in a predetermined manner to internally housed servers (compute or data storage). The bay's female connector 1116 includes a similar bundle of optical networking interfaces that are preconfigured to connect to specific switching zones in the rack (see, e.g., FIGS. 9 and 10), using the optical interconnect in the rear of the rack (again, providing backplane functionality without limitations of hardwired channels). The interconnect topology is fully configured when the system and rack are assembled and eliminates any on-site cabling within the rack or cabinet during operation.

A group of servers within a sled share an optical interconnect (blind mate) interface that distributes received signals to particular servers of a sled, either by physically routing the signals to a corresponding server or by terminating them and then redistributing via another mechanism. In one example, four optical interfaces are split evenly between two servers in a compute sled, but other allocations are possible as well. Other embodiments (e.g., with larger server groups) could include a different number of optical interconnect interfaces. In the latter case, for example, an embodiment may include a so-called microserver-style sled having several compute elements (e.g., cores) exceeding the number of available optical fibers coming from the switch. In such a case, the connections would be terminated using a local front end switch and would then be broken down into a larger number of lower speed signals to distribute to each of the cores.

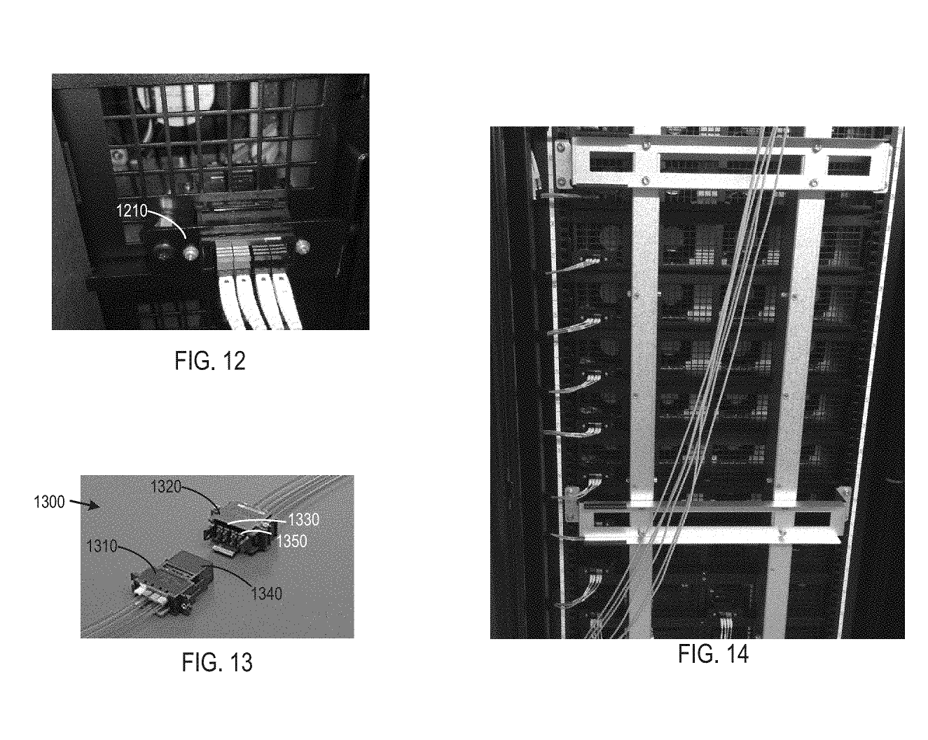

FIG. 12 shows a portion of the fiber-optic cabling at the back of the rack 106, extending from the optical connectors at a bay position and showing a detailed view of mated connectors. The mated connectors comprise blind mate connector housings encompassing four multi-fiber push on (MPO) cable connectors, with each MPO cable connector including two optical fibers for a total of eight fibers in the blind mate connector. The modules blind mate at a connector panel 1210. Accordingly, in this embodiment, each optical interconnect attachment point is provided by an MPO cable connector of a blind mate connector mounted in its connector panel 1210.

FIG. 13 shows a blind mate connector 1300. In this embodiment, the connector 1300 is a Molex HBMT™ Mechanical Transfer (MT) High-Density Optical Backplane Connector System available from Molex Incorporated of Lisle, Ill. This system of rear-mounted blind mate optical interconnects includes an adapter housing portion 1310 and a connector portion 1320. The adapter housing portion 1310 is secured to the connector panel 1210 (FIG. 12) at the rear of a bay. Likewise, the connector portion 1320 is mounted in a sled at its back side. Confronting portions of the adapter housing portion 1310 and the connector portion 1320 have both male and female attributes, according to the embodiment of FIG. 13. For example, a female receptacle 1330 of the connector portion 1320 receives a male plug 1340 of the adapter housing portion 1310. But four male ferrules 1350 projecting from the female receptacle 1330 engage corresponding female channels (not shown) within the male plug 1340. Moreover, the non-confronting portions also have female sockets by which to receive male ends of cables. Nevertheless, despite this mixture of female and male attributes, for conciseness this disclosure refers to the adapter housing portion 1310 as a female connector due to its female-style signal-carrying channels. Accordingly, the connector portion 1320 is referred to as the male portion due to its four signal-carrying male ferrules 1350. Skilled persons will appreciate, however, that this notation and arrangement are arbitrary, and a female portion could just as well be mounted in a sled such that a male portion is then mounted in a bay.

The location of the blind mate connector 1300 provides multiple benefits. For example, the fronts of the sleds are free from cables, which allows for a simple sled replacement procedure (and contributes to lower operational costs), facilitates hot swappable modules of various granularity (i.e., computing or storage servers), and provides optical interconnects that are readily retrofitted or otherwise replaced.

FIG. 14 shows the sleds installed in the rack. The sleds and components will typically have been preinstalled so that the entire rack can be shipped and installed as a single unit without any further on-site work, aside from connecting external interfaces and power to the rack. There are no cables to plug in or unplug or think about. The system has an uncluttered appearance and is not prone to cabling errors or damage.

Once a (new) sled is plugged in, it is automatically connected via the preconfigured optical interconnect to the correct switching elements. It is booted and the correct software is loaded dynamically, based on its position in the rack. A process for dynamically configuring a sled's software is described in the following paragraphs. In general, however, sled location addressing and server identification information are provided to managing software (control/orchestration layers, which vary according to deployment scenario) so that the managing software may load corresponding software images as desired for configuring the sled's software. Sleds are then brought into service, i.e., enabled as a network function, by the managing software, and the rack is fully operational. This entire procedure typically takes a few minutes, depending on the software performance.

Initially, at a high level, a user, such as a data center operator, is typically concerned with using provisioning software for programming sleds in the rack according to the sled's location, which, perforce, gives rise to a logical plane (or switching zone) established by the preconfigured optical fiber connections described previously. The identification available to the provisioning software, however, is a media access control (MAC) address. Although a MAC address is a globally unique identifier for a particular server in a sled, the MAC address does not itself contain information concerning the sled's location or the nature of its logical plane connections. But, once it can associate a MAC address with the sled's slot (i.e., its location in the rack and relationship to the optical network), the provisioning software can apply rules to configure the server. In other words, once a user can associate a sled location to a MAC address (i.e., a unique identifier), the user can use any policies it wants for setup and provisioning sleds in the slots. Typically, this will include programming the sled in the slots in specific ways for a particular data center operating environment.

Accordingly, each switch in the rack maintains a MAC address table that maps a learned MAC address to a port on which the MAC address is detected when a sled is powered on and begins transmitting network packets in the optical network. Additionally, a so-called connection map is created to list a mapping between ports and slot locations of sleds. A software application, called the rack manager software, which may be stored on a non-transitory computer-readable storage device or medium (e.g., a disk or RAM) for execution by a processing device internal or external to the switch, can then query the switch for obtaining information from its MAC address table. Upon obtaining a port number for a particular MAC address, the rack manager can then use the connection map for deriving the sled's slot location based on the obtained port number. The location is then used by the rack manager and associated provisioning software to load the desired sled software. Additional details on the connection map and rack manager and associated provisioning software are as follows.

The connection map is a configuration file, such as an Extensible Markup Language (XML) formatted file or other machine-readable instructions, that describes how each port has been previously mapped to a known corresponding slot based on preconfigured cabling between slots and ports (see, e.g., FIGS. 9 and 10). In other words, because each port on the switch is connected to a known port on a server/sled position in the rack, the connection map provides a record of this relationship in the form of a configuration file readable by the rack manager software application. The following table shows an example connection map for the switch 848 (FIG. 8) in slot 37.1 of the rack 106.

TABLE
Connection Map of Switch 848 (FIG. 8)

| Switch | | | Part | |
|---|---|---|---|---|
| Port | Slot | Serv- | (or Model) | |
| No. | “Shelf#”.“Side#” | er No. | No. | Notes |
| 1 | 5.2 | 0 | 21991101 | |
| 2 | 5.2 | 1 | 21991101 | |
| 3 | 5.1 | 0 | 21991101 | |
| 4 | 5.1 | 1 | 21991101 | |
| 5 | 7.2 | 0 | 21991101 | |
| 6 | 7.2 | 1 | 21991101 | |
| 7 | 7.1 | 0 | 21991101 | |
| 8 | 7.1 | 1 | 21991101 | |
| 9 | 9.2 | 0 | 21991101 | |
| 10 | 9.2 | 1 | 21991101 | |
| 11 | 9.1 | 0 | 21991100 | |
| 12 | 9.1 | 1 | 21991100 | |
| 13 | 11.2 | 0 | 21991100 | |
| 14 | 11.2 | 1 | 21991100 | |
| 15 | 11.1 | 0 | 21991100 | |
| 16 | 11.1 | 1 | 21991100 | |
| 17 | 13.2 | 0 | 21991100 | |
| 18 | 13.2 | 1 | 21991100 | |
| 19 | 13.1 | 0 | 21991100 | |
| 20 | 13.1 | 1 | 21991100 | |
| 21 | 15.1 | 0 | 21991102 | This and follow- |
| | | | | ing shelves are |
| | | | | full width (“#.1” |
| | | | | and no “#.2”) |
| 23 | 17.1 | 0 | 21991102 | |
| 25 | 19.1 | 0 | 21991102 | |
| 27 | 21.1 | 0 | 21991102 | |
| 29 | 23.1 | 0 | 21991102 | |
| 31 | 25.1 | 0 | 21991102 | |
| 33 | 27.1 | 0 | 21991102 | |
| 35 | 29.1 | 0 | 21991102 | |
| 37 | 31.1 | 0 | 21991102 | |
| 39 | 33.1 | 0 | 21991102 | |
| 43 | 36.1 | 0 | (HP JC772A) | Switch 856 |
| | | | | (FIG. 8) |
| 44 | 40.1 | 0 | (HP JL166A) | Internal switch |
| | | | | 846 (FIG. 8) |
| 45 | 41.1 | 0 | (HP JL166A) | External switch |
| | | | | 844 (FIG. 8) |

If a port lacks an entry in the connection map, then it is assumed that the port is unused. For example, some port numbers are missing in the example table because, in this embodiment of a connection map, the missing ports are unused. Unused ports need not be configured.

The slot number in the foregoing example is the lowest numbered slot occupied by the sled. If the height of a sled spans multiple slots (i.e., it is greater than 1U in height), then the slot positions occupied by the middle and top of the sled are not available and are not listed in the connection map. For example, the sled in slot 15 is 2U in height and extends from slot 15 to 17. Slot 16 is not available and is therefore not shown in the connection map. Slots ending in “0.2” indicate a side of a half-width shelf.

“Part No.” is a product identification code used to map to a bill of materials for the rack and determine its constituent parts. The product identification code is not used for determining the slot position but is used to verify that a specific type of device is installed in that slot.

The rack manager software application may encompass functionality of a separate provisioning software application that a user of the rack uses to install operating systems and applications. In other embodiments, these applications are entirely separate and cooperate through an application programming interface (API) or the like. Nevertheless, for conciseness, the rack manager and provisioning software applications are generally just referred to as the rack manager software. Furthermore, the rack manager software may be used to set up multiple racks and, therefore, it could be executing externally from the rack in some embodiments. In other embodiments, it is executed by internal computing resources of the rack, e.g., in a switch of the rack.

Irrespective of where it is running, the rack manager software accesses a management interface of the switch to obtain a port on which a new MAC address was detected. For example, each switch has a management interface that users may use to configure and read status from the switch. The management interface is usually accessible using a command line interface (CLI), Simple Network Management Protocol (SNMP), Hypertext Transfer Protocol (HTTP), or other user interface. Thus, the rack management software application uses commands exposed by the switch to associate a port with a learned MAC address. It then uses the port to do another lookup from the connection map of the slot number and server number. In other words, it uses the connection map's optical interconnect configuration to heuristically determine sled positions.

After the rack manager software has obtained port, MAC address, server function, and slot location information, it can readily associate the slot with the learned MAC address. With this information in hand, the correct software is loaded based on the MAC addresses. For example, the Preboot Execution Environment (PXE) is an industry standard client/server interface that allows networked computers that are not yet loaded with an operating system to be configured and booted remotely by an administrator. Another example is the Open Network Install Environment (ONIE), but other boot mechanisms may be used as well, depending on the sled.

If the cabling on the rack is changed, then the connection map is edited to reflect the cabling changes. In other embodiments, special signals carried on hardwired connections may be used to determine the location of sleds and thereby facilitate loading of the correct software.

FIGS. 12, 14, and (in particular) 15 also show fans providing local and shared cooling across multiple servers within one sled (a normalized subcomponent). Optimal cooling architecture with fans shared across multiple compute/storage elements provides for a suitable balance of air movement and low noise levels, resulting in highest availability and lower cost operations. With reference to FIG. 15, relatively large dual 80 mm fans are shown cooling two servers within a single compute sled. A benefit of this configuration is an overall noise (and cost) reduction, since the larger fans are quieter and do not have a whine characteristic of smaller 40 mm fans used in most 1U server modules. The 2U sled height provides more choices on optional components that would fit within the sled.

Skilled persons will understand that many changes may be made to the details of the above-described embodiments without departing from the underlying principles of the disclosure. The scope of the present invention should, therefore, be determined only by the following claims.

1. A rack-based system for deploying modular information technology equipment, the rack-based system comprising:
a network switch having multiple switching elements;
a rack including the network switch and multiple bays, each bay of the multiple bays having at its rear a first blind mate fiber-optic connector portion;
an optical network defined by fiber-optic cabling extending from first blind mate fiber-optic connector portions of the multiple bays to preselected switching elements of the multiple switching elements; and
multiple server sleds including compute sleds and storage sleds, each server sled of the multiple server sleds having at its back side a second blind mate fiber-optic connector portion matable with the first blind mate fiber-optic connector portion, and each server sled being sized to slide into a corresponding bay of the multiple bays so as to connect information technology equipment of the server sled to the optical network in response to mating portions of a blind mate fiber-optic connector of the server sled and the corresponding bay.

2. The rack-based system of claim 1 in which at least some of the multiple bays are two rack units (2U) high.

3. The rack-based system of claim 1 in which the multiple bays further comprise first and second sets of bays, each member of the first set of bays being sized to receive a different compute sled, and each member of the second set of bays being sized to receive a different storage sled.

4. The rack-based system of claim 3 in which the first set of bays are defined by shelves that span between lateral sides of the rack.

5. The rack-based system of claim 3 in which the second set of bays are defined by half-rack-width shelves.

6. The rack-based system of claim 3 in which the first set of bays are full-rack-width shelves and the second set of bays are half-rack-width shelves, the full-rack-width shelves being located in the rack above the half-rack-width shelves.

7. The rack-based system of claim 1 in which the network switch comprises a top of rack (ToR) switch.

8. The rack-based system of claim 1, further comprising a power supply unit installed in a lower section of the rack.

9. The rack-based system of claim 1 in which at least one of the first or second blind mate fiber-optic connector portions includes multiple mechanical transfer (MT) ferrules.

10. The rack-based system of claim 1 in which the blind mate fiber-optic connector accommodates multiple sections of optical fibers, each group of the multiple groups corresponding to a switching zone in the rack so as to establish multiple switching zones.

11. The rack-based system of claim 10 in which the multiple switching zones include a control plane network and a data plane network.

12. The rack-based system of claim 1 in which a front face of each server sled is free from cabling.

13. The rack-based system of claim 1 in which each server sled is hot swappable.

14. The rack-based system of claim 1 in which a compute sled houses multiple servers.

15. The rack-based system of claim 1 in which a storage sled houses multiple disk drives.

16. The rack-based system of claim 1, further comprising a computer-readable storage device including a connection map stored thereon, the connection map including machine-readable instructions for mapping different ones of the preselected switching elements to corresponding locations of different ones of the multiple server sleds deployed in the rack.

17. The rack-based system of claim 16 in which the computer-readable storage device includes instructions stored thereon that, when executed by a processor, cause the processor to provision the multiple server sleds with software selected by the processor based on the corresponding locations of different ones of the multiple server sleds in the rack.

18. The rack-based system of claim 1 in which the multiple bays are vertically symmetrical in the rack.
